(19) United States
(12) Patent Application Publication
(10) Pub. No.: US 2025/0006712 A1
(43) Pub. Date: Jan. 2, 2025

(54) STACKED LED CHIPS

(71) Applicant: CreeLED, Inc., Durham, NC (US)

(72) Inventors: Andre Pertuit, Raleigh, NC (US); Robert Wilcox, Rolesville, NC (US); David Suich, Durham, NC (US); Michael Check, Holly Springs, NC (US); Colin Blakely, Raleigh, NC (US)

(21) Appl. No.: 18/345,270

(22) Filed: Jun. 30, 2023

(51) Int. Cl. H01L 25/075; H01L 33/00

(52) U.S. Cl. CPC H01L 25/0756; H01L 33/0093

(57) ABSTRACT

Embodiments of a light-emitting diode (LED) device are disclosed. In some embodiments, the LED device includes a first LED device and one or more other LED devices mounted to the first LED device. By mounting the other LED devices to the first LED device, the LED devices are arranged in a stacked configuration. This allows for better light mixing of the light emitted by the various LED devices since the LED devices are at least partially aligned with one another. Different manners of stacking the LED devices are disclosed. The scope of the disclosure includes the specific embodiments disclosed as well as other combinations depending on the color mixing profile that is desired.

### FIELD OF THE DISCLOSURE

This disclosure relates to light-emitting diode (LED) devices and methods of manufacturing the same.

### BACKGROUND

Light-emitting diodes (LEDs) are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from silicon carbide, gallium nitride, gallium phosphide, aluminum nitride, gallium arsenide-based materials, and/or from organic semiconductor materials. Photons generated by the active region are emitted in all directions.

Obtaining a desired color profile requires that light from various LEDs be mixed together. Generally, each LED emits a different color of light and the light from the various LEDs are mixed together to obtain the desired color of light. Currently, however, LEDs are placed next to one another. For example, a green LED, a red LED, and a blue LED are placed in close proximity to one another to obtain white light. However, since the three LEDs are placed side by side, the amount of color that each LED contributes to the light mixing varies depending on the location. Since at most angles and locations one or more of the LEDs will be closer than a different one of the LEDs, there are variations in the color mixing profile depending on the location and angle of interest. Thus, obtaining a more consistent color profile is an important need in the industry.

### SUMMARY

Embodiments of a light-emitting diode (LED) device are disclosed. In some embodiments, the LED device includes a first LED device and one or more other LED devices mounted to the first LED device. By mounting the other LED devices to the first LED device, the LED devices are arranged in a stacked configuration. This allows for better light mixing of the light emitted by the various LED devices since the LED devices are at least partially aligned with one another. Different manners of stacking the LED devices are disclosed. The scope of the disclosure includes the specific embodiments disclosed as well as other combinations depending on the color mixing profile that is desired.

In some embodiments, a light-emitting diode (LED) device, includes: a first LED chip; and a second LED chip mounted to the first LED chip. In some embodiments, the first LED chip defines a first surface; the second LED chip defines a second surface; and the second surface of the second LED chip is mounted on the first surface of the first LED chip. In some embodiments, the first LED chip defines a first cathode contact and a first anode contact; and the second LED chip defines a second cathode contact and a second anode contact. In some embodiments, the LED device further includes a light-diffusing layer, wherein: a wavelength conversion element is mounted on the first LED chip; and the second LED chip is mounted on the wavelength conversion element. In some embodiments, the first LED chip, includes: a first growth substrate; and a first active LED region mounted on the first growth substrate; the second LED chip, includes: a second growth substrate; and a second active LED region mounted on the second growth substrate; and the second growth substrate is mounted on the first growth substrate. In some embodiments, the LED device further includes a third LED chip, wherein: the third LED chip, includes: a third growth substrate; and a third active LED region mounted on the first growth substrate; and the third growth substrate is mounted on the first growth substrate. In some embodiments, the first LED chip includes a first anode connection and a first cathode connection, wherein the first anode connection and the first cathode connection are arranged such that the first LED chip has a flip-chip configuration; and the second LED chip includes a second anode connection and a second cathode connection, wherein the second anode connection and the second cathode connection are arranged such that the second LED chip has a lateral configuration. In some embodiments, the first LED chip includes: a first growth substrate; and a first active LED region mounted on the first growth substrate; the first growth substrate defines a surface and a pocket having an opening that is flush with the surface; the second LED chip includes: a second growth substrate; and a second active LED region mounted on the second growth substrate; the second growth substrate is mounted in the pocket defined by the first growth substrate; and the pocket defines a depth that is substantially equal to a thickness of the second LED chip such that the second LED chip is substantially flush with the surface of the first growth substrate. In some embodiments, the LED device further includes a wavelength conversion element wherein: the first LED chip defining a first surface; the wavelength conversion element is mounted on a first portion of the first surface; the second LED chip defines a second surface; and the second surface of the second LED chip is mounted on a second portion of the first surface of the first LED chip, and the first portion of the first surface is different than the second portion of the first surface. In some embodiments, the first LED chip further includes a first cathode connection and a first anode connection, the first cathode connection and the first anode connection are arranged such that the first LED chip has a flip-chip configuration; and the second LED chip further includes a second cathode connection and a second anode connection, the second cathode connection and the second anode connection are arranged such that the second LED chip has a lateral configuration. In some embodiments, the LED device further includes a third LED chip, wherein the second LED chip is further mounted on the third LED chip. In some embodiments, the first LED chip includes a first anode connection and a first cathode connection, wherein the first anode connection and the first cathode connection are arranged such that the first LED chip has a lateral configuration; the second LED chip includes a second anode connection and a second cathode connection, wherein the second anode connection and the second cathode connection are arranged such that the second LED chip has a flip-chip configuration; and the third LED chip includes a third anode connection and a third cathode connection, wherein the third anode connection and the third cathode connection are arranged such that the third LED chip has the lateral configuration. In some embodiments, the second LED chip has the second anode connection mounted on the first anode connection and the second cathode connection mounted on the third cathode connection. In some embodiments, the first LED chip is mounted on a submount. In some embodiments, the submount includes traces that connect to first LED chip and the second LED chip.

In some embodiments, a method of manufacturing a light-emitting diode (LED) device, includes: providing a first LED chip; providing a second LED chip; and the second LED chip to the first LED chip. In some embodiments, the method further includes mounting the first LED chip to a submount before mounting the second LED chip to the first LED chip. In some embodiments, the method further includes connecting a first anode connection and a first cathode connection of the first LED chip to a metallic structure of the submount; and connecting a second anode connection and a second cathode connection of the second LED chip to the metallic structure of the submount. In some embodiments, mounting the second LED chip to the first LED chip includes mounting a surface of a first growth substrate of the second LED chip to a surface of a second growth substrate of the first LED chip. In some embodiments, mounting the second LED chip to the first LED chip includes mounting an anode connection of the second LED chip to an anode contact of the first LED chip and mounting a cathode connection of the second LED chip to a cathode contact of the first LED chip.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a perspective view of a light-emitting diode (LED) device that includes multiple LED chips mounted on the growth substrate of another LED chip, in accordance with some embodiments.

FIG. 2A and FIG. 2B illustrate an LED device having multiple LED chips mounted in pockets formed in the growth substrate of another LED chip.

FIG. 3 illustrates an LED device with multiple LED chips mounted on a wavelength conversion element, wherein the wavelength conversion element is mounted on another LED chip.

FIG. 4 illustrates an LED device having a wavelength conversion element mounted on one portion of the growth substrate of an LED chip and multiple other LED chips mounted on another portion of the growth substrate, in accordance with some embodiments.

FIG. 5 is an LED device having an LED device with a flip-chip configuration mounted on two LED devices that each have a lateral configuration, in accordance with some embodiments.

FIG. 6A illustrates an LED device having an LED chip with a vertical configuration and multiple other LED chips mounted on the LED chip with the vertical configuration, in accordance with some embodiments.

FIG. 6B illustrates an LED device similar to the LED device in FIG. 6A mounted on a submount, in accordance with some embodiments.

FIG. 7 illustrates an LED device having multiple LED chips mounted on an LED chip with a vertical configuration, in accordance with some embodiments.

FIG. 8 is a detailed cross-sectional view of an LED device having an LED chip with a flip-chip configuration mounted on an LED chip with a vertical configuration, in accordance with some embodiments.

FIG. 9A illustrates the LED device shown in FIG. 1 mounted on a submount, in accordance with some embodiments.

FIG. 9B-9C illustrate another LED device mounted to a submount.

FIG. 10 illustrates an LED chip that includes non-light-emitting structures, in accordance with some embodiments.

FIG. 11 is a flow diagram describing a method of manufacturing an LED device, in accordance with some embodiments.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

Embodiments of a light-emitting diode (LED) device are disclosed. In some embodiments, the LED device includes a first LED device and one or more other LED devices mounted to the first LED device. By mounting the other LED devices to the first LED device, the LED devices are arranged in a stacked configuration. This allows for better light mixing of the light emitted by the various LED devices since the LED devices are at least partially aligned with one another. Different manners of stacking the LED devices are disclosed. The scope of the disclosure includes the specific embodiments disclosed as well as other combinations depending on the color mixing profile that is desired.

Before delving into specific details of various aspects of the present disclosure, an overview of various elements that may be included in exemplary LED devices of the present disclosure is provided for context. An LED chip typically comprises an active LED structure or region that can have many different semiconductor layers arranged in various ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure can comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group Ill nitride-based material systems. Group Ill nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include silicon carbide (SiC), organic semiconductor materials, and other Group III-V systems such as gallium phosphide (GaP), gallium arsenide (GaAs), indium phosphide (InP), and related compounds.

The active LED structure may be grown on a growth substrate that can include many materials, such as sapphire, SiC, aluminum nitride (AlN), GaN, GaAs, glass, or silicon. SiC has certain advantages, such as a closer crystal lattice match to Group III nitrides than other substrates and results in Group III nitride films of high quality. SiC also has a very high thermal conductivity so that the total output power of Group III nitride devices on SiC is not limited by the thermal dissipation of the substrate. Sapphire is another common substrate for Group III nitrides and also has certain advantages, including being lower cost, having established manufacturing processes, and having good light-transmissive optical properties.

Different embodiments of the active LED structure can emit different wavelengths of light depending on the composition of the active layer and n-type and p-type layers. In certain embodiments, the active LED structure emits blue light with a peak wavelength range of approximately 430 nanometers (nm) to 480 nm, or green light with a peak wavelength range of 500 nm to 570 nm, or red light with a peak wavelength range of 600 nm to 700 nm. In certain embodiments, the active LED structure may be configured to emit light that is outside the visible spectrum, including one or more portions of the ultraviolet (UV) spectrum. The UV spectrum is typically divided into three wavelength range categories denotated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications. In certain aspects, a single LED package may include multiple LED chips, one or more of which may be configured to provide a different peak wavelength from the other LED chips.

An LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having different peak wavelength than the LED source. An LED source and one or more lumiphoric materials may be selected such that their combined output results in light with one or more desired characteristics such as color, color point, intensity, spectral density, color rendering index, etc. In certain embodiments, aggregate emissions of LED chips, optionally in combination with one or more lumiphoric materials, may be arranged to provide cool white, neutral white, or warm white light, such as within a color temperature range of 2500 Kelvin (K) to 10,000 K. In certain embodiments, lumiphoric materials having cyan, green, amber, yellow, orange, and/or red peak wavelengths may be used. In some embodiments, the combination of the LED chip and the one or more lumiphors (e.g., phosphors) emits an overall white combination of light. The one or more phosphors may include yellow (e.g., YAG: Ce), green (e.g., LuAg: Ce), and red (e.g., Ca_{i-x-y}SrₓEu_{y}AlSiN₃) emitting phosphors, and combinations thereof.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, embedded into an optical or support element, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips.

As used herein, a layer or region of a light-emitting device may be considered to be “transparent” when at least 50% or at least 80% of emitted radiation that impinges on the layer or region emerges through the layer or region. Moreover, as used herein, a layer or region of an LED is considered to be “reflective” or embody a “mirror” or a “reflector” when more than 50% or at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of UV LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength. In other embodiments, a “light-transmissive” material may be configured with lower values, such as transmitting at least 10%, or at least 25% of light having a desired wavelength, while still being useful for a particular application and suppressing other wavelengths, such as ambient light and/or sunlight. In still further embodiments, the term “light-transmissive” may be used for applications where any useful light, such as emitting wavelengths from an underlying LED, may pass through the material. The terms transparent, reflective, and light-transmissive may be defined relative to certain wavelength ranges, such as those emitted by an LED chip and/or converted by any lumiphoric materials. Specific values listed above are meant to describe average values or properties of an element or layer. It is understood that variations of these properties may be present within or across such elements or layers.

As used herein, the term “opaque” refers to materials, surfaces, particles, among others, that are either not transparent or are non-light transmitting over at least a portion of the visible light spectrum. In certain aspects, the term “opaque” may also apply to the entire visible light spectrum. The term “non-light transmitting” may be considered as transmitting less than 20%, or less than 10% of a received light, or certain wavelengths of received light. A material may further be opaque due to either light absorption or light reflection. Some materials may be opaque at certain wavelengths and transparent at others. As a non-limiting example, a red pigment may act as a color filter by absorbing light wavelengths below approximately 600 nm, where it is opaque, while transmitting light wavelengths above approximately 600 nm, where it is transparent. A layer may include a distribution of opaque materials in an amount such that the layer remains light-transmissive.

The present disclosure can be useful for LED chips having a variety of geometries, such as lateral geometries. A lateral geometry LED chip typically includes both anode and cathode electrical connections on the same side of the LED chip that is opposite a substrate, such as a growth substrate. In certain embodiments, a lateral geometry LED chip may be flip-chip mounted such that the anode and cathode connections are on a face of the active LED structure that is opposite the primary emission face of the LED chip. In this configuration, electrical traces or patterns may be provided on a mounting surface for providing electrical connections to the anode and cathode connections of the LED chip. In a flip-chip configuration, the active LED structure is configured between the substrate of the LED chip and the mounting surface. Accordingly, light emitted from the active LED structure may pass through the substrate in a desired emission direction.

As described herein, the principles of the present disclosure are applicable to various embodiments with a variety of LED chip sized, including larger area chips as well as miniature LED chips and micro-LED chips. As used herein, a large area LED chip may have lateral dimensions up to about 2000 microns (μm), while miniature LED chips may have lateral dimensions around 100 μm, and micro-LED chips may have lateral dimensions below 50 μm. In this manner, LED chips of the present disclosure may have lateral dimensions in a range from 20 μm to 2000 μm, or in a range from 20 μm to 1000 μm, or in a range from 20 μm to 100 μm, or in a range from 100 μm to 2000 μm, depending on the application.

According to aspects of the present disclosure, LED packages may include one or more elements, such as lumiphoric materials, encapsulants, light-altering materials, lenses, superstrates or support elements, adhesive elements, and electrical contacts, among others, that are provided with one or more LED chips. Light-altering materials may be arranged within LED packages to reflect or otherwise redirect light from the one or more LED chips in a desired emission direction or pattern. The term “superstrate” is used herein as a support element in an LED device, in part, to avoid confusion with other traditional substrates or submounts that may conventionally be part of LED devices, such as a growth or carrier substrate of the LED chip and/or a submount of an LED package. The term “superstrate” is not intended to limit the orientation, location, and/or composition of the structure it describes, nor various optical, electrical, thermal, and mechanical properties beyond the description of a support element as described herein. In certain embodiments, the superstrate may be composed of a transparent material, a semi-transparent material, or a light-transmissive material to various wavelengths of light provided by an LED chip and/or lumiphoric material.

As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO₂), zirconium oxide (ZrO₂), aluminum oxide (Al₂O₃), metal particles, glass fibers and/or glass particles suspended in a binder, such as silicone or epoxy. In certain aspects, the particles may have an index or refraction that is configured to refract light emissions in a desired direction. In certain aspects, light-reflective particles may also be referred to as light-scattering particles. For light-absorbing materials, the light-altering material may include at least one of carbon, silicon, metal, metal oxides (e.g., iron oxides and the like) and organic particles suspended in a binder, such as silicone or epoxy. Exemplary organic particles may include various pigments, dyes, and/or absorptive additives. Thixotropic materials may include one or more of glass fillers and fumed silica. The light-reflective materials and the light-absorbing materials may comprise nanoparticles. In certain embodiments, the light-altering material may comprise a generally white color to reflect and redirect light. In other embodiments, the light-altering material may comprise a generally opaque color, such as black or gray, for absorbing light and increasing contrast. In certain embodiments, the light-altering material includes both light-reflective material and light-absorbing material suspended in a binder. As used herein, a layer or coating of one or more light-altering materials may be referred to as a light-altering coating. In certain embodiments, a light-altering material or coating may be devoid of lumiphoric materials. Light-altering elements may also refer to modified surfaces, such as textures used for diffusion and/or scattering, that do not necessarily require added particles. In still further embodiments, light-altering materials may be provided in the form of coatings that are applied to outer sides or surfaces of light-emitting devices to control light emission.

In certain applications, it is desirable to increase the speed of manufacturing LED devices. One approach to increasing speed of manufacture is to assemble many components on a single support element (or superstrate as described below) and later separate the groups into component arrays. This can be particularly useful when creating multi-color component arrays for use in high-definition (HD) video displays. Multiple arrays can be created as a large sheet and subsequently singulated into individual arrays comprising a plurality of LED devices for each singulated portion. In this manner, a single LED device, after singulation, may be populated with multiple LED chips of different emission colors such as red, green, and blue, among others. In this regard, such LED devices may be well suited for use as pixels within HD video displays and/or signage applications. In other embodiments, larger arrays of LED chips may be formed together to provide LED components, LED tiles, LED screens, and/or LED displays.

Additionally, the elimination of various elements of a conventional LED device may streamline the manufacturing process, improve light quality, promote device miniaturization, and/or reduce costs. For example, LED devices can be assembled without the use of, or devoid of, a conventional LED package submount (e.g., a ceramic submount with traces, a lead frame structure, a printed circuit board, etc.). This may be accomplished by assembling the LEDs topside down, such that the LED is assembled on a support element, such as a transparent superstrate or a light-transmissive layer, which will become a topside outer surface in the finished product. The components can then be electrically connected through exposed electrical connection points on the opposite side of the LEDs. The device or apparatus may therefore be devoid of a traditional submount on the side of the LEDs opposite the light-transmitting side, such as, for example, a ceramic, metal, or other type of rigid material substrate upon which LEDs are often attached. An LED device built from the topside down as described herein can be considered a complete LED device, which is devoid of such a rigid submount. That is not to say that such LED devices cannot later be assembled into a larger (e.g., multiple component) device, which can, for example, include a traditional package submount.

While such single LED devices with closely-spaced LED chips of multiple colors may be well suited for use as pixels within HD video displays and/or signage applications, challenges exist in near-field and/or far-field emission patterns from such devices. For example, nonmatching far-field emission patterns provided by different LED chips (e.g., red, blue, and green LED chips) in a single package may contribute to the appearance of a color shift when viewing video displays at various angles. Emission variations can arise both from different emission patterns for the different color chips and from their geometrical placement within LED packages. In another example, near-field emissions are typically concentrated along a center of an LED device from closely-spaced LED chips, which contributes to a more pixelated appearance or reduced fill factor within video screens and displays. In this regard, when multiple LED devices with centrally concentrated near-field emission patterns are assembled together, a so-called “screen door” effect may be visible when darker lines are formed in columns and rows along boundaries of the LED devices within the display.

Support elements according to the present disclosure provide improved far-field emission patterns for increased uniformity at wider viewing angles within a display and/or improved near-field emission uniformity that increases the fill factor within each LED device, thereby reducing the screen door effect in the display. Support elements may include laminate structures with transparent superstrates and/or light-transmissive layers, and any number of materials and optical structures that exhibit light-transmissive and/or light-scattering properties relative to associated LEDs and/or lumiphoric materials. In certain embodiments, support elements may include a laminate structure of various layers or sublayers that are configured to improve near-field and/or far-field emission patterns, particularly for light-emitting devices with multiple chips that emit multiple peak wavelengths of light. The laminate films may generally be light-transmissive to light from corresponding LED chips while also exhibiting one or more of light-reflecting, light-refracting, light-absorbing, light-scattering, and/or light-diffusing properties. In particular embodiments, exemplary support elements may include a light-transparent layer that is sandwiched between two layers with increased light-reflecting, light-refracting, light-absorbing, light-scattering, and/or light-diffusing properties relative to the light-transparent layer. In this regard, the centrally located light-transparent layer may form a mixing chamber for light that may laterally propagate and internally reflect several times along the support element before ultimately escaping the LED device with improved emission uniformity. As used herein, an interior mixing chamber within a support element may also be referred to as an optical cavity.

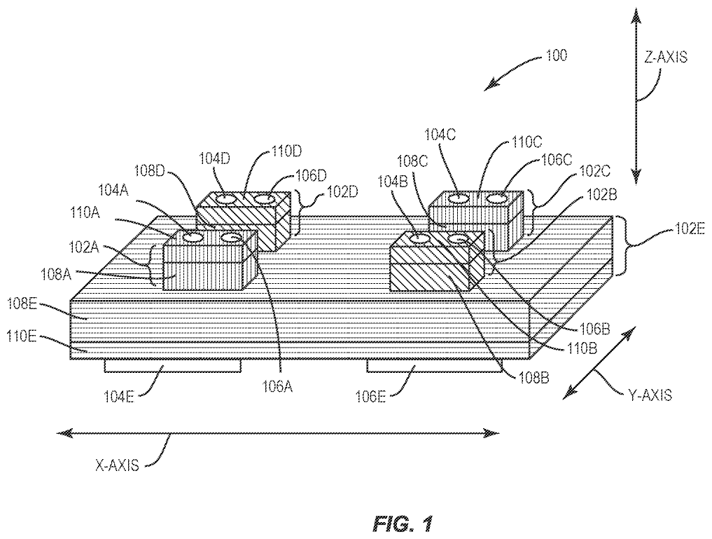

FIG. 1 is a perspective view of an LED device 100 that includes multiple LED chips 102A, 102B, 102C, 102D and 102E, in accordance with some embodiments.

Layers of the LED device 100 are stacked relative to a Z-axis, which is considered a vertical axis. There are two horizonal axes that are both orthogonal to the Z-axis. The Y-axis is a first horizontal axis that is orthogonal to the Z-axis. The X-axis is another horizontal axis that is orthogonal to both the Y-axis and the Z-axis.

The LED chips 102A, 102B, 102C, 102D are mounted to the LED chip 102E. In FIG. 1, the LED chips 102A, 102B, 102C, 102D are mounted on the LED chip 102E. The LED chip 102A has an anode connection 104A and a cathode connection 106A that are configured such that the LED chip 102A has a lateral configuration. More specifically, the LED chip 102A has a growth substrate 108A and an active region 110A. The anode connection 104A and the cathode connection 106A are accessible and exposed from the top of the active region 110A. The LED chips 102B, 102C, 102D have the same configuration as the LED chip 102A, with the corresponding components identified with the same numeral but with the letters B, C, D, respectively.

With respect to the LED chip 102E, the LED chip 102E has an anode connection 104E and a cathode connection 106E that are configured such that the LED chip 102E has a flip-chip configuration. More specifically, the LED chip 102E has a growth substrate 108E and an active region 110E. The anode connection 104E and the cathode connection 106E are accessible and exposed from the bottom of the active region 110E.

With respect to the X-axis and the Y-axis, the growth substrate 108E has an exposed X-Y surface with a surface area that is much larger than a surface area of the exposed X-Y surfaces of the LED chips 102A, 102B, 102C, 102D. For each of the LED chips 102A, 102B, 102C, 102D, the exposed X-Y surface of the growth substrates 108A, 108B, 108C, 108D is mounted on and attached to the exposed X-Y surface of the growth substrate 108E. In some embodiments, an epoxy layer is used to mount the exposed X-Y surface of the growth substrates 108A, 108B, 108C, 108D on the exposed X-Y surface of the growth substrate 108E.

In FIG. 1, the active region 110A is configured such that the LED chip 102A emits red light. An active region 110B is configured such that the LED chip 102B emits green light. An active region 110C is configured such that the LED chip 102C emits red light. An active region 110D is configured such that the LED chip 102D emits green light. The active region 110E is configured such that the LED chip 102E emits blue light. In other embodiments, the LED chips 102A, 102B, 102C, 102D, 102E are rearranged so that different combinations of the LED chips 102A, 102B, 102C, 102D, 102E emit green, red, and blue light. In still other embodiments, the LED chips 102A, 102B, 102C, 102D, 102E emit other colors. For example, in some embodiments, the LED chips 102A, 102B, 102C, 102D, 102E provide different combinations of cyan, yellow, or magenta. In this embodiment, the four LED chips 102A, 102B, 102C, 102D are mounted to the LED chip 102E. In other embodiments, any number of LED chips are mounted to the LED chip 102E.

By way of example, for display applications where the LED device 100 forms a display pixel, LED chips may be provided that are configured to emit blue light, green light, and red light. Other color combinations, inclusive of white emissions, may be provided depending on the application. Depending on the application, the LED chips 102A, 102B, 102C, 102D, 102E may define various lateral dimensions, such as in a range from 20 μm to 2000 μm, or in a range from 20 μm to 1000 μm, or in a range from 20 μm to 100 μm, or in a range from 100 μm to 2000 μm. Miniature LED chips (e.g., around 100 μm to 300 μm+/−50 μm) and micro-LED chips (e.g., below 100 μm) may be well suited for pixels in LED displays.

By mounting the LED chips 102A, 102B, 102C, 102D on the LED chip 102E, a greater intensity of the light from the LED chips 102A, 102B, 102C, 102D is mixed with the light from the LED chip 102E. This helps mitigate issues with color over angle and improves light mixing of the emitted light from each of the LED chips 102A, 102B, 102C, 102D, 102E.

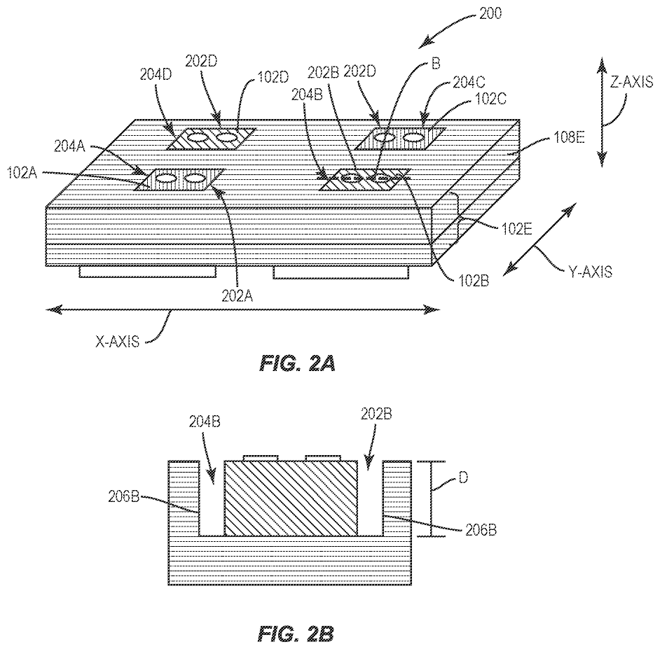

FIG. 2A and FIG. 2B illustrate another LED device 200, in accordance with some embodiments.

The LED device 200 includes the LED chips 102A, 102B, 102C, 102D and 102E described above with respect to FIG. 1. However, in this embodiment, pockets 202A, 202B, 202C, 202D are formed in the growth substrate 108E of the LED chip 102E. FIG. 2B illustrates a cross-sectional view of the pocket 202B taken along line B in FIG. 2A. Each of the pockets 202A, 202C, 202D are formed in the same manner as the pocket 202B, in accordance with some embodiments. Each pocket 202A, 202B, 202C, 202D has a depth D with respect to the Z axis. A top of an opening 204A, 204B, 204C, 204D for each of the pockets 202A, 202B, 202C, 202D is provided flush with the exposed X-Y surface of the growth substrate 108E. In certain embodiments, a depth D of each of the pockets 202A, 202B, 202C, 202D is substantially equal to a thickness of each of the LED chips 102A, 102B, 102C, 102D so that a top X-Y surface of the LED chips 102A, 102B, 102C, 102D is substantially flush (within acceptable manufacturing errors provided by LED manufacturing standards) with the exposed X-Y surface of the growth substrate 108E. In this manner, side walls (only side walls 206B are labeled in FIG. 2B with respect to the pocket 202B) of the pockets 202A, 202B, 202C, 202D substantially surround X-Z surfaces and Y-Z surfaces of the LED chips 102A, 102B, 102C, 102D. The pockets 202A, 202B, 202C, 202D thus block light from the X-Z surfaces and Y-Z surfaces of the LED chips 102A, 102B, 102C, 102D.

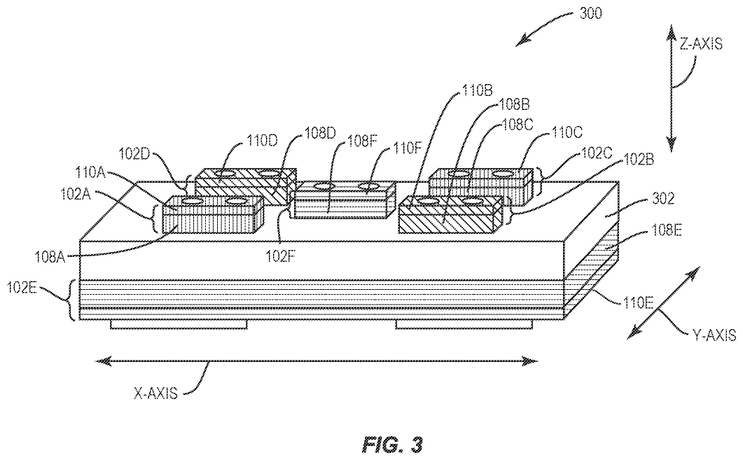

FIG. 3 illustrates another LED device 300, in accordance with some embodiments.

The LED device 300 includes the LED chips 102A, 102B, 102C, 102D, and 102E, described above with respect to FIG. 1. The LED device 300 further includes a LED chip 102F. The LED chip 102F has the same configuration as the LED chip 102A, with the corresponding components identified with the same numeral but with the letter F, respectively. However, the LED chip 102F has an active region 110F that is configured to emit blue light.

The LED chips 102A, 102B, 102C, 102D, 102F are mounted to the LED chip 102E. However, in FIG. 3, the LED device 300 further includes a wavelength conversion element 302. A bottom X-Y surface of the wavelength conversion element 302 is mounted on and attached to the top X-Y surface of the growth substrate 108E of the LED chip 102E. The growth substrates 108A, 108B, 108C, 108D, 108F of the LED chips 102A, 102B, 102C, 102D, 102F are mounted to a top X-Y surface of the wavelength conversion element 302. The wavelength conversion element 302 mixes and changes the wavelength of the light emitted by the LED chips 102A, 102B, 102C, 102D, 102E, 102F so that light emitted by the LED device 300 has a desired color profile. Wavelength conversion elements, such as the wavelength conversion element 302, include a lumiphoric material that converts a portion of light to a different wavelength. In FIG. 3, the wavelength conversion element 302 converts the light emitted by the active region 110E (in this embodiment, blue light) to another wavelength such as yellow, green, and/or red. The wavelength conversion element 302 may include a lumiphoric material layer on a transparent support element, such as glass. Alternatively, the wavelength conversion element 302 may be a so-called phosphor-in-glass structure where lumiphoric particles are embedded within a glass structure.

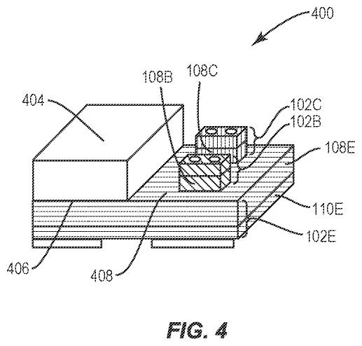

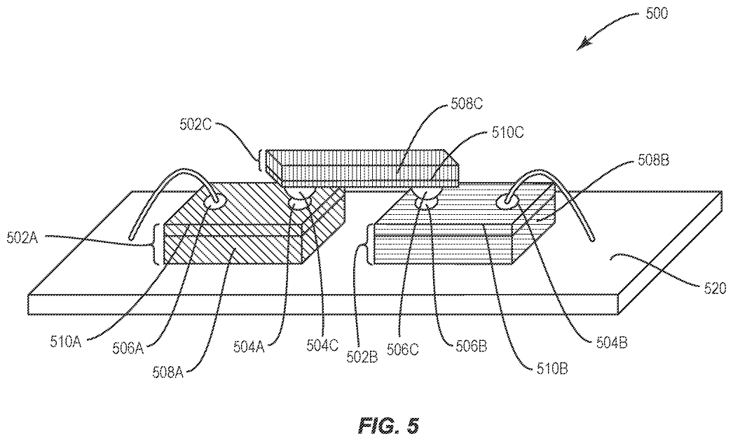

FIG. 4 illustrates another LED device 400, in accordance with some embodiments.

The LED device 400 includes the LED chips 102B, 102C, 102E but does not include the LED chips 102A, 102D, 102F. In FIG. 4, a portion 406 of the top X-Y surface of the growth substrate 108E of the LED chip 102E is covered by a wavelength conversion element 404. The wavelength conversion element 404 is thus mounted on the portion 406 of the top X-Y surface of the growth substrate 108E. A portion 408 of the top X-Y surface of the growth substrate 108E of the LED chip 102E is not covered by the wavelength conversion element 404. Instead, the growth substrate 108B of the LED chip 102B is mounted on the portion 408 and the growth substrate 108C of the LED chip 102C is mounted on the portion 408. The LED device 400 is thus configured so that light emitted by the LED device 400 has a desired color profile.

FIG. 5 is another LED device 500, in accordance with some embodiments.

The LED device 500 includes LED chips 502A, 502B, 502C. The LED chip 502A has an anode connection 504A and a cathode connection 506A that are configured such that the LED chip 502A has a lateral configuration. More specifically, the LED chip 502A has a growth substrate 508A and an active region 510A. The anode connection 504A and the cathode connection 506A are accessible and exposed from the top of the active region 510A.

The LED chip 502B has an anode connection 504B and a cathode connection 506B that are configured such that the LED chip 502B has a lateral configuration. More specifically, the LED chip 502B has a growth substrate 508B and an active region 510B. The anode connection 504B and the cathode connection 506B are accessible and exposed from the top of the active region 510B.

With respect to the LED chip 502C, the LED chip 502C has an anode connection 504C and a cathode connection 506C that are configured such that the LED chip 502C has a flip-chip configuration. More specifically, the LED chip 502C has a growth substrate 508C and an active region 510C. The anode connection 504C and the cathode connection 506C are accessible and exposed from the bottom of the active region 510C.

In FIG. 5, the anode connection 504C of the LED chip 502C is mounted on the anode connection 504A of the LED chip 502A. Also, the cathode connection 506C is mounted on the cathode connection 506B of the LED chip 502B. In FIG. 5, the bottom X-Y surface of the LED chip 502A and the bottom X-Y surface of the LED chip 502B are mounted on a submount 520, which may be part of an LED package. The cathode connection 506A of the LED chip 502A is wirebonded to a connection (not shown) on the submount 520. The anode connection 504B of the LED chip 502B is wirebonded to a connection (not shown) on the submount 520. In this manner, the LED chips 502A, 502B, 502C receive the voltage necessary to generate light. As such, the LED chips 502A, 502B, 502C are connected in series.

In FIG. 5, the active region 510A of the LED chip 502A is configured to generate green light, the active region 510B of the LED chip 502B is configured to generate blue light, and the active region 510C of the LED chip 502C is configured to generate red light. In other embodiments, other color profiles for the LED chips 502A, 502B, 502C may be utilized.

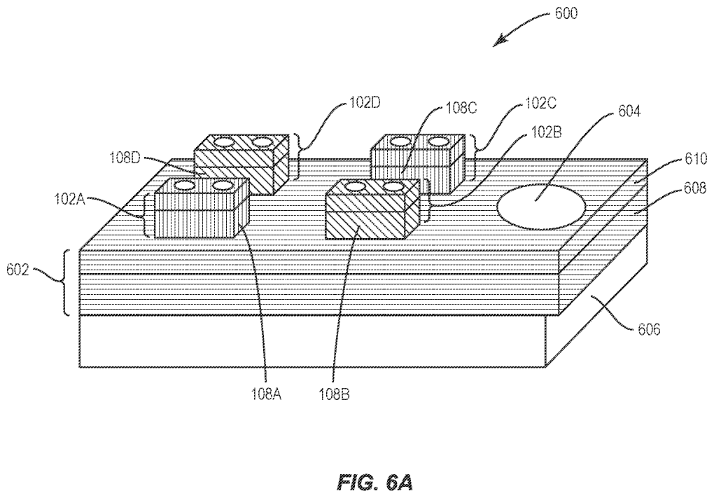

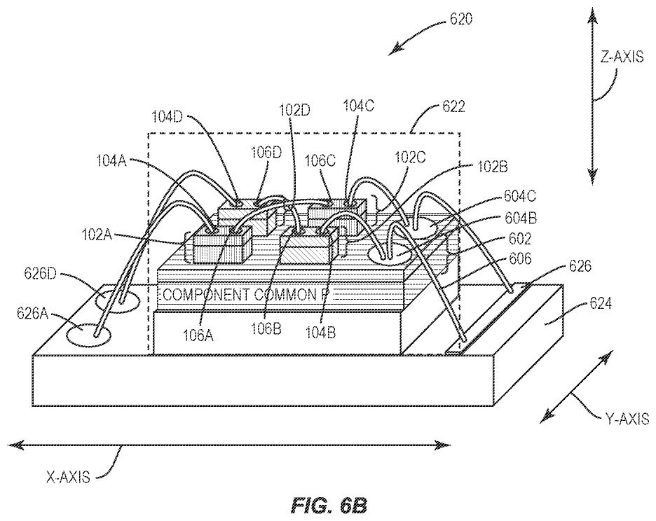

FIG. 6A illustrates another LED device 600, in accordance with some embodiments.

The LED device 600 includes the LED chips 102A, 102B, 102C, 102D described above with respect to FIG. 1. Furthermore, the LED device 600 includes an LED chip 602. The LED chip 602 has an anode connection 604 and a cathode connection 606 that are configured such that the LED chip 602 has a vertical configuration. More specifically, the LED chip 602 has a growth substrate 608 and an active region 610. The anode connection 604 is accessible and exposed from a bottom of the growth substrate 608. In FIG. 6A, the cathode connection 606 is provided as a conductive pad that is exposed at the bottom of the growth substrate 608. The anode connection 604 is accessible and exposed from the top of the active region 610. In FIG. 6A, the cathode connection 606 is a pillar that forms a contact and is exposed from the top of the active region 610. The growth substrates 108A, 108B, 108C, 108D are mounted on the active region 610 of the LED chip 602. In FIG. 6A, the active region 610 of the LED chip 602 is configured to emit blue light. In other embodiments, the LED chips 102A, 102B, 102C, 102D, 602 may have different color combinations. The cathode connection 606 is an N-pad bond metal, which is mounted on a submount (not shown), in accordance with some embodiments. A wirebond (not shown) is used to connect to the anode connection 604, in accordance with some embodiments.

FIG. 6B is an embodiment of an LED device 620, in accordance with some embodiments.

The LED device 620 includes an LED device 622 and a submount 624. The LED device 622 is the same as the LED device 600 shown in FIG. 6A, except that the LED chip 602 includes an anode connection 604B and an anode connection 604C that are accessible from the top of the active region 610. Also, the anode connection 104C and the cathode connection 106C are reversed in orientation relative to the X-axis in comparison to the embodiment in FIG. 1. Furthermore, the anode connection 104B and the cathode connection 106B are reversed in orientation relative to the X-axis in comparison to the embodiment in FIG. 1.

The LED device 622 is mounted on the submount 624. More specifically, in FIG. 6B, the cathode connection 606 is mounted on the submount 624. In some embodiments, the submount 624 includes a metallic structure that includes a ground plate (not shown), wherein the cathode connection 606 is mounted on the ground plate of the submount 624. In some embodiments, the submount 624 is part of an LED package (not shown). The metallic structure of the submount 624 includes a conductive pad 626A, a conductive trace 626, and a conductive pad 626D. The conductive pad 626A is configured to have an applied voltage that is operable so that the LED chip 102A emits red light. The conductive pad 628D is configured to have an applied voltage that is operable so that the LED chip 102D emits green light.

The metallic structure of the submount 624 provides the voltages for the LED chips 102A, 102B, 102C, and 102D to operate. In FIG. 6B, the anode connection 104A is wirebonded to the conductive pad 626A. Furthermore, the anode connection 104D is wirebonded to the conductive pad 626D. The anode connection 604B is wirebonded to the conductive trace 626. Thus, the anode connection 604B also has an applied voltage for an LED device that emits green light. The anode connection 104B of the LED chip 104B is wirebonded to the anode connection 604B.

In FIG. 6B, the anode connection 604C is wirebonded to the conductive trace 626. Thus, the anode connection 604C also has an applied voltage for an LED device that emits red light. The anode connection 104C of the LED chip 104C is wirebonded to the anode connection 604C. Basically, having the trace 626 creates a common p connection for the LED chip 102C and the LED chip 102B. As explained above, the LED chip 102C and the LED chip 102B have separate n connections thereby allowing each to emit different colors of light. With the trace 628 connected and wirebonded to the pads 604C, 604D on the LED chip 102E, the trace 628 also provides a p connection for the LED chip 602. The pads 604C, 604D on the LED chip 602 are separate but the pads 604C, 604D are electrically connected to the to the trace 626 to share the common p. So effectively, any one or combo of the LED chips 102A-102D can be turned on and off by controlling the connection of n sides of the pads 626A, 626D, 624). For example, if just the LED chip 602 is turned on, the voltage would be 3V in some embodiments. If the LED chip 602 and one string of LED chips 102C, 102D or 102A, 102B were on then the voltage would be 3V+2x, where is the voltage of the lateral chips 102A-102D.

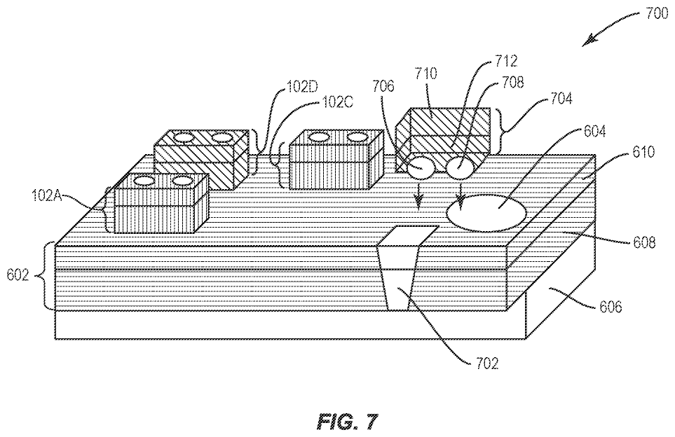

FIG. 7 is another LED device 700, in accordance with some embodiments.

The LED device 700 includes the LED chips 102A, 102C, 102D, 602 in the same arrangement as described above with respect to FIG. 6A. The LED device 700 also includes the N-pad bond metal 606 described above. However, in this embodiment, the LED chip 602 includes a conductive pillar 702 that extends through the active region 610 and the growth substrate 608. The conductive pillar 702 is connected to the anode connection 604 at the bottom of the growth substrate 608 and is exposed from the top of the active region 610. Thus although the LED chip 602 has a vertical configuration, both an anode contact (i.e., the top of the conductive pillar 702) and a cathode contact (i.e., the top of the cathode connection) are exposed from the top of the LED chip 602.

Taking the place of the LED chip 102B in FIG. 6A is an LED chip 704. With respect to the LED chip 704, the LED chip 704 has an anode connection 706 and a cathode connection 708 that are configured such that the LED chip 704 has a flip-chip configuration. More specifically, the LED chip 704 has a growth substrate 710 and an active region 712. The anode connection 706 and the cathode connection 708 are accessible and exposed from the bottom of the active region 712.

In FIG. 7, the LED chip 704 is mounted such that the anode connection 706 is mounted on the anode contact formed by the conductive pillar 702. Furthermore, the cathode connection 708 is mounted on the cathode contact formed by the cathode connection 606. In this manner, the LED chip 704 is configured to receive voltages to generate light from the active region 712. In FIG. 7, the active region 712 is configured to emit green light. In other embodiments, the active region 712 is configured to emit any suitable color of light depending on a desired color profile.

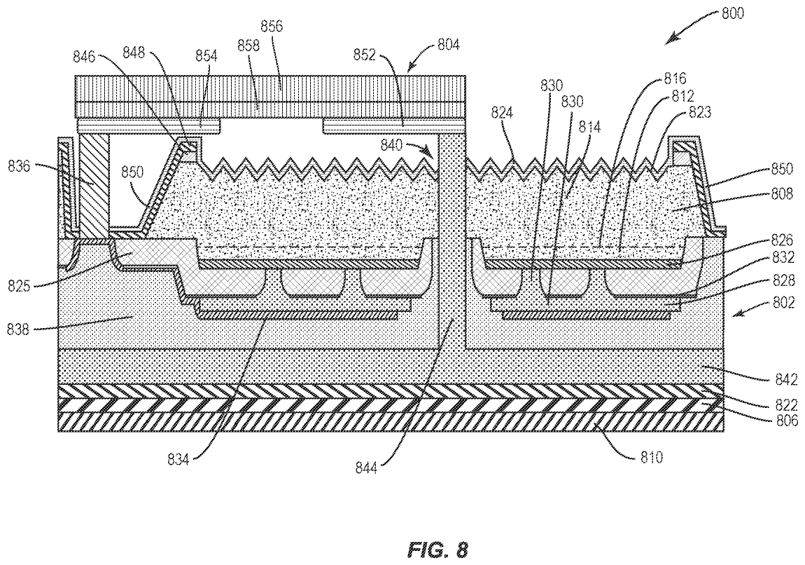

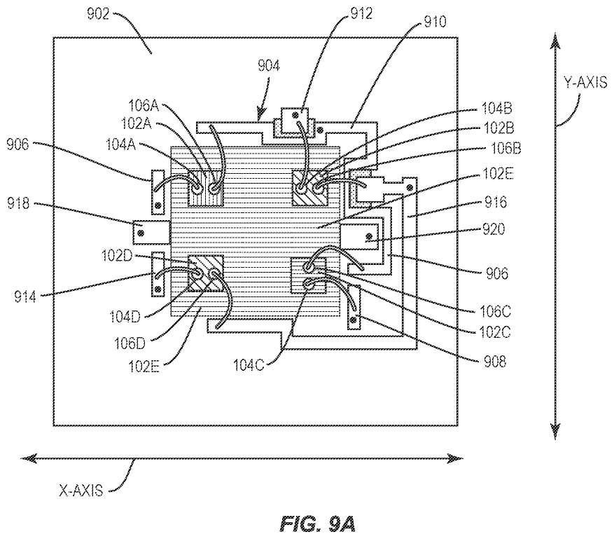

FIG. 8 is a generalized cross-section of an LED device 800 having a LED chip 802 having vertical chip configuration and a LED chip 804 having a flip-chip configuration.

The LED chip 804 is mounted to the LED chip 802. The LED chip 802 includes a B-doped Si substrate 806. The LED chip 802 is similar to the LED chip 602 shown in FIG. 7, except that unlike the LED chip 602 in FIG. 7, the growth substrate has been removed from the LED chip 802. As such, the LED chip 802 includes an active LED structure 808, which is attached to the B-doped Si substrate 806. The B-doped Si substrate 806 is formed on and attached to a layer 810 and to a bond metal 822. The layer 810 forms a bottom side anode connection, in accordance with some embodiments. In some embodiments, the layer 810 is mounted on and electrically attached to a submount (not shown). The submount may be part of an LED package. The layer 810 is formed from a Ti/Ni/AuSn alloy in accordance with some embodiments.

The active LED structure 808 generally refers to portions of the LED chip 802 that include semiconductor layers, such as epitaxial semiconductor layers, that form a structure that generates light when electrically activated. The active LED structure 808 is formed on and supported by the B-doped Si substrate 806 that is made from silicon or doped silicon. In certain embodiments, the B-doped Si substrate 806 and the layer 810 are formed from an electrically conductive material such that the B-doped Si substrate 806 and the layer 810 are part of electrically conductive connections to the active LED structure 808.

The active LED structure 808 may generally comprise a p-type layer 812, an n-type layer 814, and an active layer 816 arranged between the p-type layer 812 and the n-type layer 814. The active LED structure 808 may include many additional layers such as, but not limited to, buffer layers, nucleation layers, super lattice structures, un-doped layers, cladding layers, contact layers, current-spreading layers, and light extraction layers and elements. Additionally, the active layer 816 may comprise a single quantum well, a multiple quantum well, a double heterostructure, or super lattice structures. In FIG. 8, the p-type layer 812 is arranged between the active layer 816 and the B-doped Si substrate 806 such that the p-type layer 812 is closer to the B-doped Si substrate 806 than the n-type layer 814. The active LED structure 808 may initially be formed by epitaxially growing or depositing the n-type layer 814, the active layer 816, and the p-type layer 812 sequentially on a growth substrate. The active LED structure 808 may then be flipped and bonded to the B-doped Si substrate 806 by way of one or more bond metals 822 and the growth substrate is removed. In this manner, a top surface 823 of the n-type layer 814 forms a primary light-extracting face of the LED chip 802. In certain embodiments, the top surface 823 is formed to have a textured or patterned surface for improving light extraction. In other embodiments, the doping order may be reversed such that the n-type layer 814 is arranged between the active layer 816 and the B-doped Si substrate 806. In FIG. 8, a passivation layer 824 is formed over the top surface 823. In portions of the top surface 823 that are patterned, the passivation layer 824 is formed on and directly over the textured/patterned portions of the top surface 823.

The LED chip 802 may include a first reflective layer 825 provided on the p-type layer 812. In certain embodiments, a current spreading layer 826 may be provided between the p-type layer 812 and the first reflective layer 825. The current spreading layer 826 may include a thin layer of a transparent conductive oxide such as indium tin oxide (ITO) or a thin metal layer such as Pt, although other materials may be used. The first reflective layer 825 may comprise many different materials and preferably comprises a material that presents an index of refraction step with the material of the active LED structure 808 to promote total internal reflection (TIR) of light generated from the active LED structure 808. Light that experiences TIR is redirected without experiencing absorption or loss and can thereby contribute to useful or desired LED chip emission. In certain embodiments, the first reflective layer 825 comprises a material with an index of refraction lower than the index of refraction of the active LED structure 808 material. The first reflective layer 825 may comprise many different materials, with some having an index of refraction less than 2.3, while others can have an index of refraction less than 2.15, less than 2.0, and less than 1.5. In certain embodiments, the first reflective layer 825 comprises a dielectric material, such as silicon dioxide (SiO₂) and/or silicon nitride (SiN). It is understood that many dielectric materials can be used such as SiN, SiNₓ, Si₃N₄, Si, germanium (Ge), SiO₂, SiOₓ, titanium dioxide (TiO₂), tantalum pentoxide (Ta₂O₅), ITO, magnesium oxide (MgOₓ), zinc oxide (ZnO), and combinations thereof. In certain embodiments, the first reflective layer 825 may include multiple alternating layers of different dielectric materials, e.g., alternating layers of SiO₂ and SiN that symmetrically repeat or are asymmetrically arranged. Some Group III nitride materials such as GaN can have an index of refraction of approximately 2.4, SiO₂ can have an index of refraction of approximately 1.48, and SiN can have an index of refraction of approximately 1.9. Embodiments with the active LED structure 808 comprising GaN and the first reflective layer 825 comprising SiO₂ may form a sufficient index of refraction step between the two to allow for efficient TIR of light. The first reflective layer 825 may have different thicknesses depending on the type of materials used, with some embodiments having a thickness of at least 0.2 microns (μm). In some embodiments, the first reflective layer 825 can have a thickness in the range of 0.2 μm to 0.7 μm, while in some embodiments the thickness can be approximately 0.5 μm.

The LED chip 802 may further include a second reflective layer 828 that is on the first reflective layer 825 such that the first reflective layer 825 is arranged between the active LED structure 808 and the second reflective layer 828. The second reflective layer 828 may include a metal layer that is configured to reflect light from the active LED structure 808 that may pass through the first reflective layer 825. The second reflective layer 828 may comprise many different materials such as Ag, gold (Au), Al, nickel (Ni), titanium (Ti) or combinations thereof. The second reflective layer 828 may have different thicknesses depending on the type of materials used, with some embodiments having a thickness of at least 0.1 μm, or in a range including 0.1 μm to 0.7 μm, or in a range including 0.1 μm to 0.5 μm, or in a range including 0.1 μm to 0.3 μm. As illustrated, the second reflective layer 828 may include or form one or more reflective layers 830 that provide an electrically conductive path through the first reflective layer 825. In this manner, the one or more reflective layers 830 may extend through an entire thickness of the first reflective layer 825. In certain embodiments, the second reflective layer 828 is a metal reflective layer and the reflective layer 830 comprise reflective layer metal vias. Accordingly, the first reflective layer 825, the second reflective layer 828, and the reflective layer 830 form a reflective structure of the LED chip 802 that is on the p-type layer 812. As such, the reflective structure may comprise a dielectric reflective layer and a metal reflective layer as disclosed herein. In certain embodiments, the reflective layer 830 comprises the same material as the second reflective layer 828 and is formed at the same time as the second reflective layer 828. In other embodiments, the reflective layer 830 may comprise a different material than the second reflective layer 828. Certain embodiments may also comprise an adhesion layer 832 that is positioned at one or more interfaces between the first reflective layer 825 and the second reflective layer 828 and/or interfaces between the first reflective layer 825 and the current spreading layer 826 to promote improved adhesion therebetween. Many different materials can be used for the adhesion layer 832, such as titanium oxide (TiO, TiO₂), titanium oxynitride (TION, TiₓO_{y}N), tantalum oxide (TaO, Ta₂O₅), tantalum oxynitride (TaON), aluminum oxide (AIO, AlₓO_{y}) or combinations thereof, with a preferred material being TiON, AIO, or AlₓO_{y}. In certain embodiments, the adhesion layer comprises AlₓO_{y}, where 1≤x≤4 and 1≤y≤6. In certain embodiments, the adhesion layer comprises AlₓO_{y}, where x=2 and y=3, or Al₂O₃. The adhesion layer 832 may be deposited by electron beam deposition that may provide a smooth, dense, and continuous layer without notable variations in surface morphology. The adhesion layer 832 may also be deposited by sputtering, chemical vapor deposition, plasma enhanced chemical vapor deposition, or atomic layer deposition (ALD).

The LED chip 802 may also comprise a barrier layer 834 on the second reflective layer 828 to prevent migration of material of the second reflective layer 828, such as Ag, to other layers. Preventing this migration helps the LED chip 802 maintain efficient operation throughout its lifetime. The barrier layer 834 may comprise an electrically conductive material, with suitable materials including but not limited Ti, Pt, Ni, Au, tungsten (W), and combinations or alloys thereof. In certain embodiments, the barrier layer 834 is arranged to laterally extend beyond portions of the active LED structure 808 or a peripheral border of the active LED structure 808 in order to provide an electrical connection with a p-contact 836. In this regard, an electrical path between the p-contact 836 and the p-type layer 812 may include the barrier layer 834, the second reflective layer 828, and the reflective layer 830. In other embodiments, the polarity may be reversed such that the p-contact 836 is replaced with an n-contact that is electrically coupled to the n-type layer 814 and electrical connections to the p-type layer 812 are made through the B-doped Si substrate 806. A passivation layer 838 is included on the barrier layer 834 as well as any portions of the second reflective layer 828 that may be uncovered by the barrier layer 834. The passivation layer 838 protects and provides electrical insulation for the LED chip 802 and can comprise many different materials, such as a dielectric material including but not limited to silicon nitride. In certain embodiments, the passivation layer 838 is a single layer, and in other embodiments, the passivation layer 838 comprises a plurality of layers. In certain embodiments, the passivation layer 838 may include one or more metal-containing interlayers arranged or embedded therein that may function as a crack stop layer for any cracks that may propagate through the passivation layer 838 as well as an additional light reflective layer.

In FIG. 8, the active LED structure 808 forms a first opening 840 or recess that extends through the p-type layer 812, the active layer 816, the n-type layer 814, and the passivation layer 824. The first opening 840 may be formed by a subtractive material process, such as etching, that is applied to the active LED structure 808 before bonding with the B-doped Si substrate 806. As used herein, the first opening 840 may also be referred to as an active LED structure opening. As illustrated, a portion of the first reflective layer 825, and adhesion layer 832, is arranged to cover sidewall surfaces of the p-type layer 812, the active layer 816, and the n-type layer 814 within the first opening 840. The passivation layer 838 extends along the first reflective layer 825 in the first opening 840 and is arranged on a surface of the n-type layer 814. The LED chip 802 further includes an n-contact metal layer 842 that is arranged on the passivation layer 838 and across the LED chip 802. At the first opening 840, the n-contact metal layer 842 extends into the first opening 840 to form an n-contact interconnect 844, which may be referred to as an n-contact via. In this manner, the first opening 840 may be defined where portions of the n-contact metal layer 842, the n-contact interconnect 844, the passivation layer 838, and the first reflective layer 825 extend into the active LED structure 808. As such, the n-contact metal layer 842 and the n-contact interconnect 844 may be integrally formed to provide an electrical connection to the n-type layer 814 through the first opening 840. In other embodiments, the n-contact metal layer 842 and the n-contact interconnect 844 may be separately formed and may comprise the same or different materials. In certain embodiments, the n-contact metal layer 842 and the n-contact interconnect 844 include a single layer or a plurality of layers that include conductive metals, such as one or more of Al, Ti, and alloys thereof. The n-contact interconnect 844 is formed as a pillar that forms an anode contact at the top. The n-contact interconnect 844 extends through the active region 808 and the passivation layer 824 to be exposed through the top of the LED chip 802.

As illustrated, the p-contact 836 may be formed on the barrier layer 834, and one or more top passivation layers 846, 848 may be provided on one or more top or side surfaces of the n-type layer 814 for additional electrical insulation. In FIG. 8, the top passivation layer 848 is arranged to cover mesa sidewalls 850 of the active LED structure 808. The top passivation layers 846, 848 may comprise separate layers of a continuous layer of dielectric material, such as silicon nitride. During fabrication of the mesa for the active LED structure 808, an etching step is applied to the active LED structure 808 from the n-type layer 814. The etching step effectively forms the mesa sidewalls 850 with sloped surfaces along the perimeter of the active LED structure 808. However, etchants may follow boundaries of the first reflective layer 825, the adhesion layer 832, and the barrier layer 834 outside the mesa sidewalls 850. In such instances, integrity of such layers may be compromised due to undercutting and/or erosion from the etchant, thereby leading to increased risk of moisture ingress, performance degradation, and/or reduced chip reliability. The passivation layer 824 includes portions that are formed on the top passivation layers 846, 848 of the mesa sidewalls 850.

With respect to the LED chip 804, the LED chip 804 has a cathode connection 852 and an anode connection 854 that are configured such that the LED chip 804 has a flip-chip configuration. More specifically, the LED chip 804 has a growth substrate 856 and an active region 858. The cathode connection 852 and the anode connection 854 are accessible and exposed from the bottom of the active region 858. In FIG. 8, the cathode connection 852 is mounted on the n-contact interconnect 844 and the anode connection 854 is mounted to the p-contact 836. In this manner, the LED chip 804 receives voltages to generate light through the active region 858.

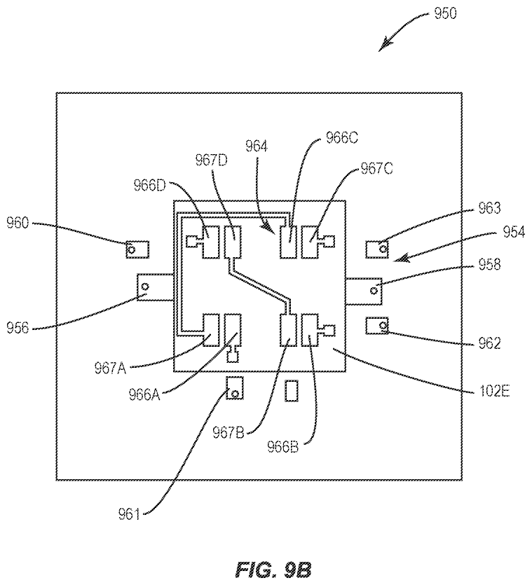

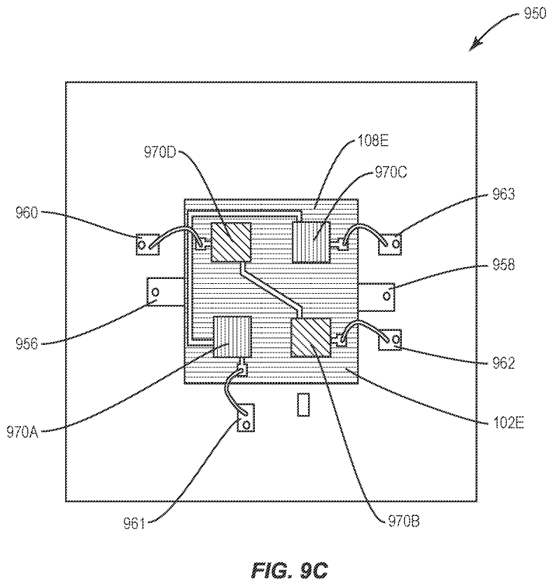

FIG. 9A is a LED device 900, in accordance with some embodiments.

The LED device 900 includes the LED device 100 described above in FIG. 1 mounted to a submount 902. More specifically, the LED chip 102E is mounted on to a metallic structure 904 integrated into the submount 902. The metallic structure 904 receives the various voltages to power the different LED chips 102A, 102B, 102C, 102D, 102E.

A metallic portion 906 of the metallic structure 904 includes a trace and a via. The anode connection 104A of the LED chip 102A is wirebonded to the metallic portion 906 that has a voltage applied for the anode connection 104A. A metallic portion 908 of the metallic structure 904 includes a trace and a via. The anode connection 104C of the LED chip 102C is wirebonded to the metallic portion 908 that has a voltage applied for the anode connection 104C. A metallic portion 910 includes connected traces where one of the traces extends primarily parallel to the X-axis and the other trace extends primarily parallel to the Y-axis. The metallic portion 910 further includes a via. The metallic portion 910 has a voltage applied for cathode connections 106A, 106C of the LED chips 102A, 102C. Each of the cathode connections 106A, 106C is wirebonded to the metallic portion 910.

A metallic portion 912 of the metallic structure 904 includes a trace and a via. The anode connection 104B of the LED chip 102B is wirebonded to the metallic portion 912 that has a voltage applied for the anode connection 104B. A metallic portion 914 of the metallic structure 904 includes a trace and a via. The anode connection 104D of the LED chip 102D is wirebonded to the metallic portion 914 that has a voltage applied for the anode connection 104D. A metallic portion 916 includes connected traces where one of the traces extends primarily parallel to the X-axis and the other trace extends primarily parallel to the Y-axis. The metallic portion 916 further includes a via. The metallic portion 916 has a voltage applied for cathode connections 106B, 106D of the LED chips 102B, 102D. Each of the cathode connections 106B, 106D is wirebonded to the metallic portion 916.

A metallic portion 918 extends beneath the LED chip 102E. The anode connection 104E (See FIG. 1) of the LED chip 102E is connected to the metallic portion 918. The metallic portion 918 includes a trace and a via. The metallic portion 918 is configured to receive a voltage for the anode connection 104E.

A metallic portion 920 extends beneath the LED chip 102E. The cathode connection 106E (See FIG. 1) of the LED chip 102E is connected to the metallic portion 920. The metallic portion 920 includes a trace and a via. The metallic portion 920 is configured to receive a voltage for the cathode connection 106E.

FIG. 9B and FIG. 9C each show an LED device 950, in accordance with some embodiments.

The LED device 950 includes the LED chip 102E mounted on to a metallic structure 954. The metallic structure 954 has been integrated into the submount 952. A metallic portion 956 extends beneath the LED chip 102E. The anode connection 104E (See FIG. 1) of the LED chip 102E is connected to the metallic portion 956. The metallic portion 956 is configured to receive a voltage for the anode connection 104E.

A metallic portion 958 extends beneath the LED chip 102E. The cathode connection 106E (See FIG. 1) of the LED chip 102E is connected to the metallic portion 958. The metallic portion 958 is configured to receive a voltage for the cathode connection 106E. The metallic structure 954 also includes metallic portions, 960, 961, 962, 963.

A metallic structure 964 is mounted on the growth substrate 108E of the LED chip 102E. The metallic structure 964 includes an anode connector 966A and a cathode connection 967A. An LED chip 970A is mounted to the LED chip 102E. In this embodiment, the LED chip 970A has a flip-chip configuration. Accordingly, an anode connection (not explicitly shown) of the LED chip 970A is connected to the anode connector 966A while the cathode connection (not explicitly shown of the LED chip 970A is connected to the cathode connector 967A. In this embodiment, the LED chip 970A is configured to emit red light. The anode connector 966 is wirebonded to the metallic portion 961. The metallic portion 961 is configured to receive a voltage for a red LED.

The metallic structure 964 includes an anode connector 966A and a cathode connection 967A. An LED chip 970A is mounted to the LED chip 102E. In this embodiment, the LED chip 970A has a flip-chip configuration. Accordingly, an anode connection (not explicitly shown) of the LED chip 970A is connected to the anode connector 966A while the cathode connection (not explicitly shown) of the LED chip 970A is connected to the cathode connector 967A. In this embodiment, the LED chip 970A is configured to emit red light. The anode connector 966A is wirebonded to the metallic portion 961. The metallic portion 961 is configured to receive a voltage for a red LED.

The metallic structure 964 includes an anode connector 966B and a cathode connection 967B. An LED chip 970B is mounted to the LED chip 102E. In this embodiment, the LED chip 970B has a flip-chip configuration. Accordingly, an anode connection (not explicitly shown) of the LED chip 970B is connected to the anode connector 966B while the cathode connection (not explicitly shown) of the LED chip 970B is connected to the cathode connector 967B. In this embodiment, the LED chip 970B is configured to emit green light. The anode connector 966B is wirebonded to the metallic portion 962. The metallic portion 962 is configured to receive a voltage for a green LED.

The metallic structure 964 includes an anode connector 966C and a cathode connection 967C. An LED chip 970C is mounted to the LED chip 102E. In this embodiment, the LED chip 970C has a flip-chip configuration. Accordingly, an anode connection (not explicitly shown) of the LED chip 970C is connected to the anode connector 966C while the cathode connection (not explicitly shown) of the LED chip 970C is connected to the cathode connector 967C. In this embodiment, the LED chip 970C is configured to emit red light. The anode connector 966C is wirebonded to the metallic portion 963. The metallic portion 963 is configured to receive a voltage for a red LED.

The metallic structure 964 includes an anode connector 966D and a cathode connection 967D. An LED chip 970D is mounted to the LED chip 102E. In this embodiment, the LED chip 970D has a flip-chip configuration. Accordingly, an anode connection (not explicitly shown) of the LED chip 970D is connected to the anode connector 966D while the cathode connection (not explicitly shown) of the LED chip 970D is connected to the cathode connector 967D. In this embodiment, the LED chip 970D is configured to emit green light. The anode connector 966D is wirebonded to the metallic portion 960. The metallic portion 960 is configured to receive a voltage for a green LED.

The metallic structure 964 also includes a trace that connects the cathode connector 967A with the cathode connector 967C. The cathode connectors 967A, 967C are thus at the same voltage since the cathode connectors 967A, 967C are cathode connectors 967A, 967C for the red LED chips 970A, 970C.

The metallic structure 964 also includes a trace that connects the cathode connector 967B with the cathode connector 967D. The cathode connectors 967B, 967D are thus at the same voltage since the cathode connectors 967B, 967D are cathode connectors 967B, 967D for the green LED chips 970B, 970D. In some embodiments, the LED chips 970A-970D have a vertical configuration instead of flip chip configuration. In still other embodiments, only some of the LED chips 970A-970D have a flip chip configuration while only some of the LED chips 970A-970D have vertical configuration. For example, in some embodiments, the red LED chips 970A, 970C have a vertical chip configuration while the green LED chips 970B, 970D have a flip chip configuration. Also, in this embodiment, the LED chip 102E has a flip chip configuration. In other embodiments, the LED chip 102E could have a flip chip configuration or a vertical configuration. These and other combinations are apparent to one of ordinary skill in the art in light of this disclosure.

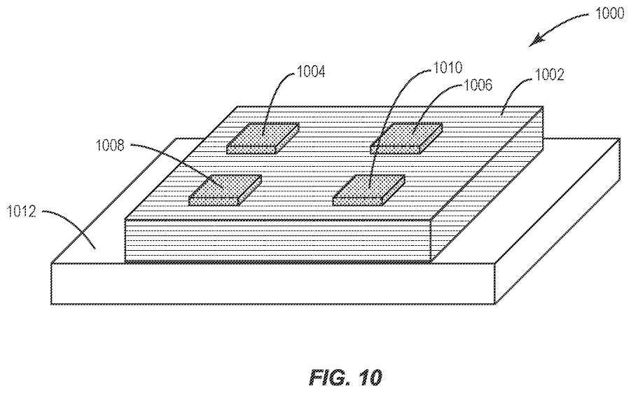

FIG. 10 is an LED device 1000, in accordance with some embodiments.

The LED device 1000 includes an LED chip 1002. Non-light-emitting structures 1004, 1006, 1008, 1010 are mounted on the LED device 100. The LED device 1000 has a flip-chip configuration. In other embodiments, the LED device 1000 can have other configurations such as a vertical configuration or a lateral configuration. The non-light-emitting structures 1004, 1006, 1008, 1010 can be fabricated where the non-light-emitting structures 1004, 1006, 1008, 1010 are deactivated. For example, deactivated regions may be formed by an added fabrication step, such as ion implantation, that intentionally damages certain p-type regions of the LED chip 1002. In another embodiment, non-mirror structures are placed that are registered with the non-light-emitting structures 1004, 1006, 1008, 1010 to reduce light output. The non-light-emitting structures 1004, 1006, 1008, 1010 may include light-absorbing structures in accordance with some embodiments. The LED chip 1002 is mounted on a submount 1012, which may be part of an LED package.

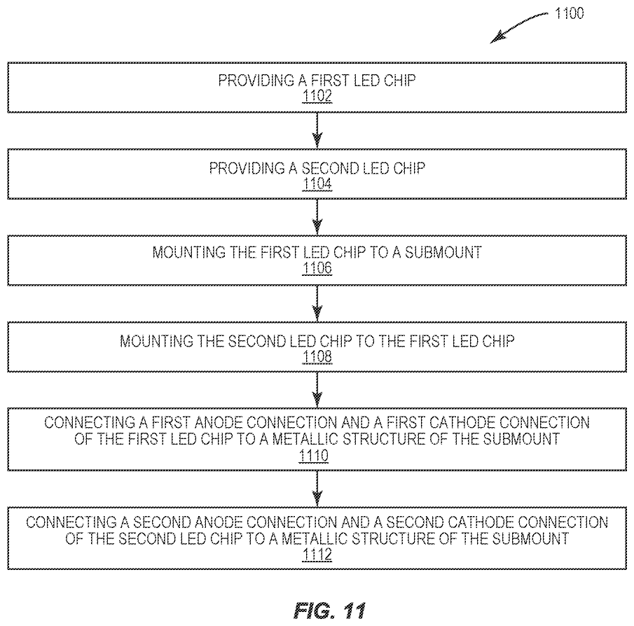

FIG. 11 is a flow diagram 1100 of a method of manufacturing an LED device, in accordance with some embodiments.

Embodiments of the flow diagram 1100 can be used to manufacture the LED device 100 in FIG. 1, the LED device 200 in FIG. 2A and FIG. 2B, the LED device 300 in FIG. 3, the LED device 400 in FIG. 4, the LED device 500 in FIG. 5, the LED device 600 in FIG. 6A, the LED device 700 in FIG. 7, the LED device 800 in FIG. 8, the LED device 900 in FIG. 9A, the LED device 952 in FIG. 9B-9C and the LED device 1000 in FIG. 10. The flow diagram 1100 includes blocks 1102-1112. Flow begins at the block 1102.

At the block 1102, a first LED chip is provided. Examples of the first LED chip are the LED chip 102E in FIG. 1, FIG. 3, and FIG. 4, the LED chip 202 in FIG. 2, the LED chips 502A, 502B in FIG. 5, the LED chip 602 in FIG. 6A and FIG. 7, and the LED chip 802 in FIG. 8. Flow then proceeds to the block 1104. At the block 1104, a second LED chip is provided. Examples of the second LED chip are the LED chips 102A, 102B, 102C, 102D in FIG. 1, FIG. 2A, FIG. 3, FIG. 4, FIG. 6A, FIG. 7, and FIG. 9, the LED chip 102F in FIG. 3, the LED chip 502C in FIG. 5, the LED chip 704 in FIG. 7, the LED chip 804 in FIG. 8, and the LED chips 970A, 970B, 970C, 970D in FIG. 9B, 9C. Flow then proceeds to the block 1106.

At the block 1106, the first LED chip is mounted to a submount. Examples of the submount include the submount 902 in FIG. 9A and the submount 952 in FIG. 9B, 9C. Flow then proceeds to the block 1108.

At the block 1108, the second LED chip is mounted on the first LED chip. Examples of the second LED chip being mounted on the first LED chip are shown in FIG. 1-FIG. 9C. In some embodiments, a surface of a first growth substrate of the second LED chip is mounted to a surface of a second growth substrate of the first LED chip. Examples of a surface of a first growth substrate of the second LED chip being mounted to a surface of the second growth substrate of the first LED chip include FIG. 1, FIG. 2A, FIG. 2B, FIG. 4, and FIG. 9A. In some embodiments, an anode connection of the second LED chip is mounted to an anode contact of the first LED chip and a cathode connection of the second LED chip is mounted to a cathode contact of the first LED chip. Examples of an anode connection of the second LED chip being mounted to an anode contact of the first LED chip and a cathode connection of the second LED chip being mounted to a cathode contact of the first LED chip include FIG. 5, FIG. 7, and FIG. 8. In some embodiments, block 1106 is performed before block 1108. In some embodiments, block 1108 is performed before block 1106. Flow then proceeds to the block 1110.

At the block 1110, a first anode connection and a first cathode connection of the first LED chip is connected to a metallic structure of the submount. An example of the first anode connection is the anode connection 104E in FIG. 1. An example of the first cathode connection is the cathode connection 106E in FIG. 1. An example of the metallic structure is the metallic structure 904 in FIG. 9A. Flow then proceeds to the block 1112.

At the block 1112, a second anode connection and a second cathode connection of the second LED chip are connected to the metallic structure of the submount. Examples of the second anode connection are each of the anode connections 104A-104D in FIG. 9A. Examples of the second cathode connection are each of the cathode connections 106A-106D in FIG. 9A.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) device, comprising:
a first LED chip; and
a second LED chip mounted to the first LED chip.

2. The LED device of claim 1, wherein:
the first LED chip defines a first surface;
the second LED chip defines a second surface; and
the second surface of the second LED chip is mounted on the first surface of the first LED chip.

3. The LED device of claim 1, wherein:
the first LED chip defines a first cathode contact and a first anode contact; and
the second LED chip defines a second cathode contact and a second anode contact.

4. The LED device of claim 1, further comprising a light-diffusing layer, wherein:
a wavelength conversion element is mounted on the first LED chip; and
the second LED chip is mounted on the wavelength conversion element.

5. The LED device of claim 1, wherein:
the first LED chip, comprises:
a first growth substrate; and
a first active LED region mounted on the first growth substrate;
the second LED chip, comprises:
a second growth substrate; and
a second active LED region mounted on the second growth substrate; and
the second growth substrate is mounted on the first growth substrate.

6. The LED device of claim 5, further comprising a third LED chip, wherein:
the third LED chip, comprises:
a third growth substrate; and
a third active LED region mounted on the first growth substrate; and
the third growth substrate is mounted on the first growth substrate.

7. The LED device of claim 5, wherein:
the first LED chip comprises a first anode connection and a first cathode connection, wherein the first anode connection and the first cathode connection are arranged such that the first LED chip has a flip-chip configuration; and
the second LED chip comprises a second anode connection and a second cathode connection, wherein the second anode connection and the second cathode connection are arranged such that the second LED chip has a lateral configuration.

8. The LED device of claim 1, wherein:
the first LED chip comprises:
a first growth substrate; and
a first active LED region mounted on the first growth substrate;
the first growth substrate defines a surface and a pocket having an opening that is flush with the surface;
the second LED chip comprises:
a second growth substrate; and
a second active LED region mounted on the second growth substrate;
the second growth substrate is mounted in the pocket defined by the first growth substrate; and
the pocket defines a depth that is substantially equal to a thickness of the second LED chip such that the second LED chip is substantially flush with the surface of the first growth substrate.

9. The LED device of claim 1, further comprising a wavelength conversion element wherein:
the first LED chip defining a first surface;
the wavelength conversion element is mounted on a first portion of the first surface;
the second LED chip defines a second surface; and
the second surface of the second LED chip is mounted on a second portion of the first surface of the first LED chip, and the first portion of the first surface is different than the second portion of the first surface.

10. The LED device of claim 9, wherein:
the first LED chip further comprises a first cathode connection and a first anode connection, the first cathode connection and the first anode connection are arranged such that the first LED chip has a flip-chip configuration; and
the second LED chip further comprises a second cathode connection and a second anode connection, the second cathode connection and the second anode connection are arranged such that the second LED chip has a lateral configuration.

11. The LED device of claim 1, further comprising a third LED chip, wherein the second LED chip is further mounted on the third LED chip.

12. The LED device of claim 11, wherein:
the first LED chip comprises a first anode connection and a first cathode connection, wherein the first anode connection and the first cathode connection are arranged such that the first LED chip has a lateral configuration;
the second LED chip comprises a second anode connection and a second cathode connection, wherein the second anode connection and the second cathode connection are arranged such that the second LED chip has a flip-chip configuration; and
the third LED chip comprises a third anode connection and a third cathode connection, wherein the third anode connection and the third cathode connection are arranged such that the third LED chip has the lateral configuration.

13. The LED device of claim 12, wherein the second LED chip has the second anode connection mounted on the first anode connection and the second cathode connection mounted on the third cathode connection.

14. The LED device of claim 1, wherein the first LED chip is mounted on a submount.

15. The LED device of claim 14, wherein the submount includes traces that connect to first LED chip and the second LED chip.

16. A method of manufacturing a light-emitting diode (LED) device, comprising:
providing a first LED chip;
providing a second LED chip; and
mounting the second LED chip to the first LED chip.

17. The method of claim 16, further comprising:
mounting the first LED chip to a submount before mounting the second LED chip to the first LED chip.

18. The method of claim 17, further comprising:
connecting a first anode connection and a first cathode connection of the first LED chip to a metallic structure of the submount; and
connecting a second anode connection and a second cathode connection of the second LED chip to the metallic structure of the submount.

19. The method of claim 17, wherein mounting the second LED chip to the first LED chip comprises mounting a surface of a first growth substrate of the second LED chip to a surface of a second growth substrate of the first LED chip.

20. The method of claim 16, wherein mounting the second LED chip to the first LED chip comprises mounting an anode connection of the second LED chip to an anode contact of the first LED chip and mounting a cathode connection of the second LED chip to a cathode contact of the first LED chip.
